(19) United States
(12) Patent Application Publication
(10) Pub. No.: US 2011/0007049 A1
(43) Pub. Date: Jan. 13, 2011

(54) TFT, SHIFT REGISTER, SCAN SIGNAL LINE DRIVING CIRCUIT, AND DISPLAY DEVICE

(76) Inventors: Tetsuo Kikuchi, Osaka (JP); Shinya Tanaka, Osaka (JP); Hajime Imai, Osaka (JP); Hideki Kitagawa, Osaka (JP); Chikao Yamasaki, Osaka (JP); Yoshiharu Kataoka, Osaka (JP)

Correspondence Address: HARNESS, DICKEY & PIERCE, P.L.C., P.O. BOX 8910, RESTON, VA, 20195, US

(21) Appl. No.: 12/736,158

(22) PCT Filed: Jan. 30, 2009
(86) PCT No.: PCT/JP2009/051630

§ 371 Date: Sep. 16, 2010

(30) Foreign Application Priority Data
Jun. 12, 2008 (JP) 2008-154046

(51) Int. Cl. G09G 5/00; H01L 33/08; H01L 33/16

(52) U.S. Cl. 345/208; 257/59; 257/72; 257/E33.004; 257/E33.053

(57) ABSTRACT

A TFT includes, in at least one embodiment, a capacitor formed: so as to have a region where a first capacitor electrode connected to a source electrode and a second capacitor electrode connected to a gate electrode are arranged to be stacked in a thickness direction and mutually opposed across a first dielectric layer therebetween; and so as to have a region where the first capacitor electrode and a third capacitor electrode connected to the gate electrode are arranged to be stacked in the thickness direction and mutually opposed across a second dielectric layer therebetween with a coupling between the first capacitor electrode and the third capacitor electrode and a coupling between the first capacitor electrode and the second capacitor electrode formed over mutually opposite faces of the first capacitor electrode. This realizes a TFT which can save a footprint of a capacitor connected to a TFT body section.

### TECHNICAL FIELD

The present invention relates to a TFT including a capacitor that is added between a gate and a source.

### BACKGROUND ART

In recent years, monolithic integration of a gate driver has been developed for the purpose of cost reduction. In the monolithic integration, the gate driver is formed from amorphous silicon on a liquid crystal panel. The term “monolitic gate driver” is also associated with the terms such as “gate driver-free”, “built-in gate driver in panel”, and “gate in panel”. For example, Patent Literature 1 discloses shift registers of monolithic gate drivers.

FIG. 7 shows circuit configuration of each shift register stage disclosed in Patent Literature 1.

The following describes essential structure and operations of this circuit. FIG. 11 shows the structure of an n-th stage of shift register stages cascaded with each other. To an input terminal 12, a gate output from a preceding stage is supplied. This supply causes an output transistor 16 to be turned ON through a drain of a transistor 18. A bootstrap capacitor 30 is connected between a gate and a source of the output transistor 16. When a clock signal C1 in High level is supplied to the output transistor 16 from its drain side during ON-state of the output transistor 16, a gate potential of the output transistor 16 sharply increases to a level greater than power source voltage due to capacitive coupling between the gate and source of the output transistor 16 through the bootstrap capacitor 30. This substantially decreases a resistance between the source and drain of the output transistor 16. Then, the clock signal C1 in High level is outputted to a gate bus line 118, and this gate output is supplied to an input of a subsequent stage.

FIG. 8 shows a plan view of elements used when such a bootstrap capacitor is built into a display panel.

A bootstrap capacitor 101b shown in FIG. 8, as part of a TFT 101, is connected to a TFT body section 101a. In a case where a display panel is made from amorphous silicon or the like material with lower mobility, it is a widespread practice that the TFTs monolithically built into the display panel are patterned to have a much larger channel width than standard for decrease in resistance between a source and drain of the TFT body section 101a. Therefore, the TFT body section 101a shown in FIG. 11 secures a large channel width, with such an arrangement that comb-shaped source electrode 102 and drain electrode 103 are arranged to be mutually opposed in such a manner that the source electrode 102 and the drain electrode 103 are engaged with each other. Under a region of the engagement between the source electrode 102 and the drain electrode 103, a gate electrode 104 is provided. The bootstrap capacitor 101b is formed such that a first capacitor electrode 102a led out from the source electrode 102 of the TFT body section 101a and a second capacitor electrode 104a led out from the gate electrode 104 of the TFT body section 101a are arranged to be stacked and mutually opposed across a gate dielectric layer therebetween.

In addition, the first capacitor electrode 102a is connected to an output OUT of a shift register stage, and the output OUT is connected to a gate bus line GL via a contact hole 105.

FIG. 9 shows a cross-sectional view taken along the line X-X′ in FIG. 8.

As shown in the cross-sectional view of FIG. 8, the arrangement in FIG. 13 is such that: a gate metal GM, a gate dielectric layer 106, an i layer 107 formed from Si, an n+ layer 108 formed from Si, a source metal SM, and a passivation layer 109 are stacked on a glass substrate 100 in this order. The gate electrode 104, the second capacitor electrode 104a, and the gate bus line GL are all formed from the gate metal GM that has been formed in a concurrent manufacturing process. The source electrode 102, the drain electrode 103, and the first capacitor electrode 102a are all formed from the source metal SM that has been formed in the concurrent manufacturing process. The i layer 107 is a layer that serves as a channel forming region in the TFT body section 101a. The n+ layer 108 is provided as a source/drain contact layer between the i layer 107 and the source electrode 102 and between the i layer 107 and the drain electrode 103.

The above-described transistor including the bootstrap capacitor is also disclosed in Patent Literature 2, etc.

### Citation List

Patent Literature 1

Japanese Patent No. 3863215 (Registration Date: Oct. 6, 2006)

Patent Literature 2

Japanese Patent Application Publication, Tokukaihei, No. 8-87897 A (Publication Date: Apr. 2, 1996)

### SUMMARY OF INVENTION

The conventional TFT provided with a bootstrap capacitor requires being large in size so that the TFT body section secures a large channel width, as described previously. Therefore, it is inevitable that manufacturing of TFTs with low yield seriously decreases a proportion of non-defective panels obtained. However, with increase of a load connected to an output of a TFT including the bootstrap capacitor, a capacitance value required for the bootstrap capacitor to obtain a satisfactory bootstrap effect increases. Accordingly, the bootstrap capacitor occupies a large area on a panel.

A magnitude of such a capacitance value depends on circuit configuration and specification of a display panel. However, the capacitance value is equal to or greater than 3 pF for a 7-inch panel, for example. A greater screen size further increases the capacitance value. Therefore, the bootstrap capacitor 101b shown in FIG. 8 is extremely large in size. As an example is given a 7-inch WVGA display device with a monolithically fabricated gate driver which device performs gate scanning for three color lines of RGB under the condition where a capacitance value of the bootstrap capacitor 101b is 3 pF. Assume that a dot pitch in the gate scanning direction is 63 μm in an arrangement where the gate driver is disposed in one of two regions adjoining a display region, and a gate dielectric layer (SiNx) has a relative permittivity of 6.9 and has a layer thickness of 4100 Å. In this case, the bootstrap capacitor 101b is such that a side H along the gate scanning direction is 50 μm, and the other side W is 400 μm. This results in extremely large picture frame size of the display device.

Thus, the conventional TFT provided with a bootstrap capacitor has the problem that a footprint of the bootstrap capacitor is extremely large.

The present invention has been attained in view of the above program caused by the conventional arrangement, and an object thereof is to realize a TFT which can save a footprint of a capacitor connected to the TFT body section, and a shift register including the TFT, a scan signal line driving circuit, and a display device, all of which include the TFT.

In order to solve the above problem, a TFT of the present invention is a TFT comprising: a capacitor formed: so as to have a region where a first capacitor electrode connected to a source electrode and a second capacitor electrode connected to a gate electrode are arranged to be stacked in a thickness direction and mutually opposed across a first dielectric layer therebetween; and so as to have a region where the first capacitor electrode and a third capacitor electrode connected to the gate electrode are arranged to be stacked in the thickness direction and mutually opposed across a second dielectric layer therebetween with a coupling between the first capacitor electrode and the third capacitor electrode and a coupling between the first capacitor electrode and the second capacitor electrode formed over mutually opposite faces of the first capacitor electrode.

According to the above invention, the capacitor included in the TFT is arranged such that capacitance formed between the first capacitor electrode and the second capacitor electrode is connected in parallel to capacitance formed between the first capacitor electrode and the third capacitor electrode. Therefore, depending upon a thickness of each of the first and second dielectric layers, the capacitor included in the TFT can be arranged such that a footprint of the capacitor on the panel can be reduced, as compared with the conventional arrangement without parallel connection. This makes it possible to reduce a width of a picture frame region of the display device, as compared with the conventional arrangement. That is, it is possible to reduce the picture frame size. This, in turn, eliminates the need for increase of a footprint of the capacitor element of the TFT on the panel.

As described above, the present invention produces the effect of realizing a TFT which can save a footprint of the capacitor connected to the TFT body section.

In order to solve the above problem, a TFT of the present invention is such that the first capacitor electrode is formed from source metal, the second capacitor electrode is formed from gate metal, and the third capacitor electrode is formed from a transparent electrode or a reflecting electrode.

The above invention produces the effect that the capacitor included in the TFT can be easily formed with use of a metallic material that is an original material for the TFT.

In order to solve the above problem, a TFT of the present invention is such that the first dielectric layer is a gate dielectric layer, and the second dielectric layer is a passivation layer.

The above invention produces the effect that the capacitor included in the TFT can be easily formed with use of a dielectric material that is an original material for the TFT.

In order to solve the above problem, a TFT of the present invention is such that the third capacitor electrode is connected to the gate electrode, through contact with the gate electrode via a contact hole which is formed in a stack of the first and second dielectric layers.

The above invention produces the effect that the third capacitor electrode can be easily connected to the gate electrode with use of the first and second dielectric layers provided between the first capacitor electrode and the third capacitor electrode.

In order to solve the above problem, a TFT of the present invention is such that the TFT is manufactured with use of amorphous silicon.

The above invention produces the effect of reducing a footprint of a capacitor of a TFT manufactured from amorphous silicon, which TFT generally has a large channel width and has a large footprint, can be reduced, thus preventing a footprint of the entire TFT from greatly increasing.

In order to solve the above problem, a TFT of the present invention is such that the TFT is manufactured with use of microcrystalline silicon.

A TFT using microcrystal silicon has higher mobility than an amorphous silicon TFT. As such, the above invention produces the effect of making the transistor size small in comparison with the amorphous silicon TFT. Moreover, using microcrystal silicon in a TFT realizes a small-footprint TFT, which is advantageous for a slim picture frame. It is also possible to curb variations in threshold voltage caused by application of DC biases.

In order to solve the above problem, a shift register of the present invention includes a plurality of stages composed of transistors, wherein at least one of the transistors is the above TFT.

The above invention produces the effect of enabling manufacturing of a shift register with its footprint saved.

In order to solve the above problem, a scan signal line driving circuit of the present invention includes the above shift register, wherein the shift register is used to generate a scan signal for a display device.

The above invention produces the effect of enabling manufacturing of a scan signal line driving circuit with its footprint saved.

In order to solve the above problem, a scan signal line driving circuit of the present invention is such that the TFT is an output transistor that outputs the scan signal. Further, the scan signal line driving circuit may be such that from the first capacitor electrode, a lead-out line connected via a contact hole to a scan signal line is led out.

The above invention produces the effect that a TFT for which high driving ability is required can be manufactured with its footprint saved, by using the TFT as an output transistor that outputs a scan signal.

In order to solve the above problem, a display device of the present invention comprises the above scan signal line driving circuit.

The above invention produces the effect of enabling manufacturing of a display device in such a state that a footprint of a picture frame region is saved.

In order to solve the above problem, a display device of the present invention is such that the scan signal line driving circuit is formed on a display panel so as to be monolithically integrated with a display region.

The above invention produces the effect that it can make up for the disadvantages that the display device requires a large capacitance and that the TFT cannot help but having a large channel width. Consequently, it is possible to manufacture a display device in which the scan signal line driving circuit is formed on the display panel so as to be monolithically integrated with the display region in such a state that a footprint of the scan signal line driving circuit is saved.

In order to solve the above problem, a display device of the present invention comprises a display panel in which the above TFT is formed.

The above invention produces the effect of realizing a display device in such a state that a footprint of the TFT is saved.

Additional objects, features, and strengths of the present invention will be made clear by the description below. Further, the advantages of the present invention will be evident from the following explanation in reference to the drawings.

### BRIEF DESCRIPTION OF DRAWINGS

FIG. 1

FIG. 1 is a plan view showing an embodiment of the present invention and showing the structure of a TFT.

FIG. 2

FIG. 2 shows cross-sectional views of the TFT shown in FIG. 1, wherein (a) is a cross-sectional view taken along the line A-A′, and (b) is a cross-sectional view taken along the line B-B′.

FIG. 3

FIG. 3 is a block diagram showing an embodiment of the present invention and showing the structure of a display device.

FIG. 4

FIG. 4 is a circuit block diagram showing the structure of a shift register included in the display device shown in FIG. 3.

FIG. 5

FIG. 5 is an explanatory view of a shift register stage included in the shift register shown in FIG. 4, wherein (a) is a circuit diagram showing the structure of the shift register stage, and (b) is a timing chart showing operations of the circuit shown in (a).

FIG. 6

FIG. 6 is a timing chart showing operations of the shift register shown in FIG. 4.

FIG. 7

FIG. 7 is a circuit diagram showing the conventional art and showing the structure of a shift register stage.

FIG. 8

FIG. 8 is a plan view showing the conventional art and showing the structure of a TFT.

FIG. 9

FIG. 9 is a cross-sectional view taken along the line X-X′ in FIG. 8.

### REFERENCE SIGNS LIST

1 Liquid crystal display device (display device)
61 TFT
61b Capacitor
62 Source electrode
64 Gate electrode
62a First capacitor electrode
64a Second capacitor electrode
80a Third capacitor electrode
66 Gate dielectric layer (first dielectric layer)
69 Passivation layer (second dielectric layer)
Tr4 Transistor (TFT)
CAP Bootstrap Capacitor (capacitor)

### DESCRIPTION OF EMBODIMENTS

The following will describe one embodiment of the present invention with reference to FIGS. 1 through 6.

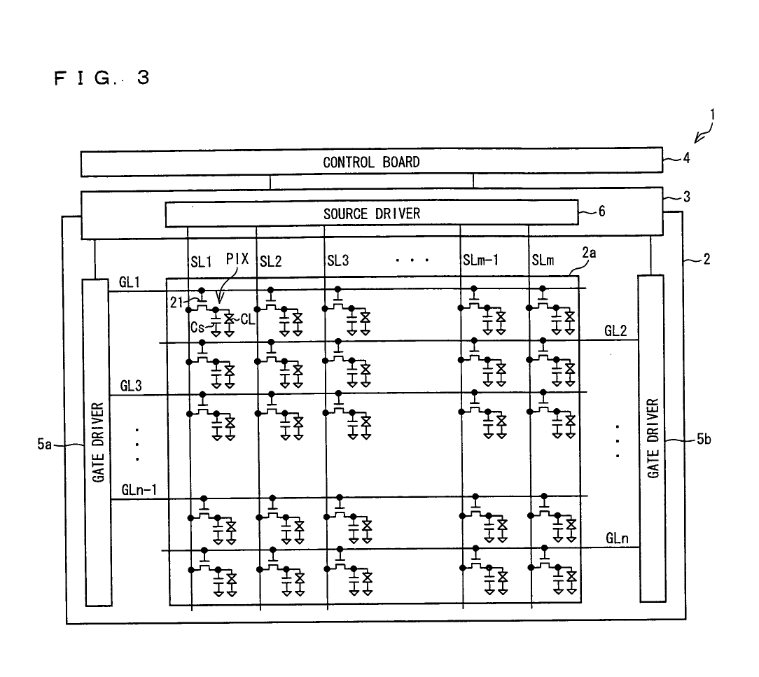

FIG. 3 shows the configuration of a liquid crystal display device 1 that is a display device according to the present embodiment.

The liquid crystal display device 1 includes a display panel 2, a flexible printed circuit board 3, and a control board 4.

The display panel 2 is an active matrix display panel arranged such that, using amorphous silicon, polycrystalline silicon, CG silicon, microcrystalline silicon, or the like silicon, a display region 2a, a plurality of gate bus lines GL, a plurality of source bus lines SL, and gate drivers 5a and 5b are built onto a glass substrate. The display region 2a is a region where a plurality of pixels PIX are arranged in a matrix manner. Each of the pixels PIX includes a TFT 21 that is a selection element of the pixel, a liquid crystal capacitor CL, and an auxiliary capacitor Cs. A gate of the TFT 21 is connected to the gate bus line GL, and a source of the TFT 21 is connected to the source bus line SL. The liquid crystal capacitor CL and auxiliary capacitor Cs are connected to a drain of the TFT 21.

The plurality of gate bus lines GL are gate bus lines GL1, GL2, GL3, . . . and GLn. Among these, the gate bus lines GL in a first group consisting of the alternate gate bus lines GL1, GL3, GL5, . . . are connected to respective outputs of the gate driver 5a, and the gate bus lines GL in a second group consisting of the other alternate gate bus lines GL2, GL4, GL6, . . . are connected to respective outputs of the gate driver 5b. The plurality of source bus lines SL are source bus lines SL1, SL2, SL3, . . . SLm, which are connected to respective outputs of a source driver 6 that will be described later. Although not shown, an auxiliary capacitor line is formed to apply an auxiliary capacitor voltage to each of the auxiliary capacitors Cs of the pixels PIX.

The gate driver 5a is provided in one of two regions adjoining the display region 2a of the display panel 2 in a direction in which the gate bus lines GL extend, and sequentially supplies a gate pulse to each of the gate bus lines GL1, GL3, GL5, . . . of the first group. The gate driver 5b is provided in the other region adjoining the display region 2a of the display panel 2, and sequentially supplies a gate pulse to each of the gate bus lines GL2, GL4, GL6, . . . of the second group. These gate drivers 5a and 5b are built into the display panel 2 so as to be monolithically integrated with the display region 2a. Examples of the gate drivers 5a and 5b can include all gate drivers referred to with the terms such as “monolithic gate driver”, “gate driver-free”, “built-in gate driver in panel”, and “gate in panel”.

The flexible printed circuit board 3 includes the source driver 6. The source driver 6 supplies a data signal to each of the source bus lines SL. The control board 4 is connected to the flexible printed circuit board 3 and supplies necessary signals and power to the gate drivers 5a and 5b and the source driver 6. The signals and power to be supplied to the gate drivers 5a and 5b from the control board 4 pass through the flexible printed circuit board 3 and are then supplied to the gate driver 15 on the display panel 2.

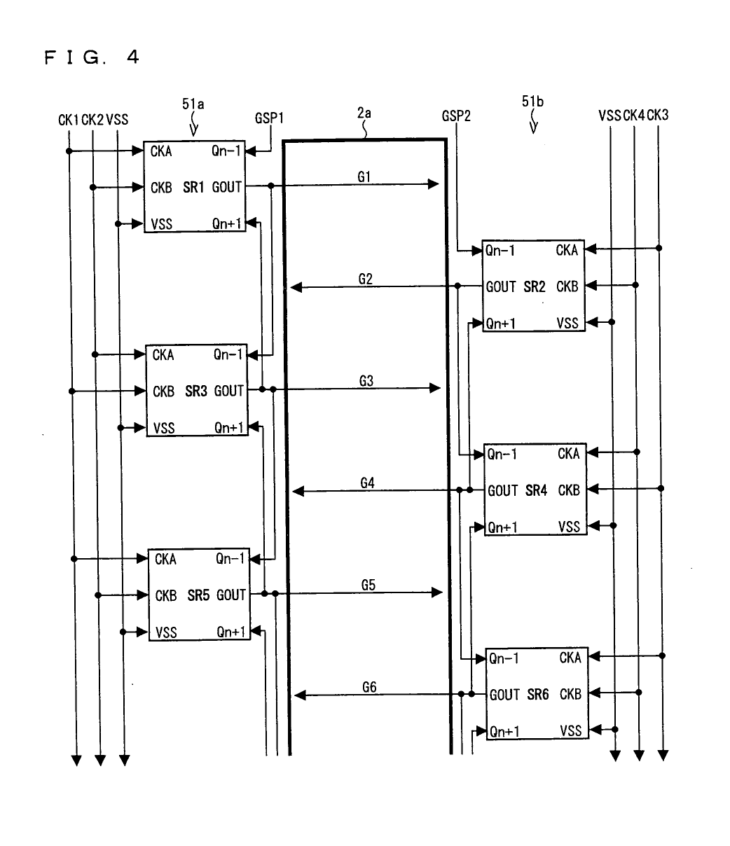

FIG. 4 shows the configurations of the respective gate drivers 5a and 5b.

The gate driver 5a includes a first shift register 51a having a plurality of cascaded shift register stages SR (SR1, SR3, SR5, . . . ) therein. Each of the shift register stages SR includes a set input terminal Qn−1, an output terminal GOUT, a reset input terminal Qn+1, clock input terminals CKA and CKB, and a Low power source input terminal VSS. From the control board 4 are supplied a clock signal CK1, a clock signal CK2, a gate start pulse GSP1, and Low power source VSS (For convenience of explanation, the same reference sign as that for the Low power source input terminal VSS is used). The Low power source VSS may be at negative potential, at ground potential, or at positive potential. However, the Low power source VSS is herein assumed at negative potential to ensure OFF state of the TFTs.

In the first shift register 51a, an output from the output terminal GOUT of a j-numbered (j=1, 2, 3, . . . , i=1, 3, 5, . . . , j=(i+1)/2) shift register stage SRi is a gate output Gi to be outputted to an i-th gate bus line GLi.

To the set input terminal Qn−1 of a first shift register stage SR1 that lies at one of opposite ends in the scanning direction, the gate start pulse GSP1 is supplied. To the respective set input terminals Qn−1 of the j-numbered second and succeeding shift register stages SRi, gate outputs Gi−2 of preceding shift register stages SRi−2 are supplied. Further, to the respective reset input terminals Qn+1 thereof, gate outputs Gi+2 of subsequent shift register stages SRi+2 are supplied.

In the alternate j-numbered shift register stages SR that start from the first shift register stage SR1, the clock signal CK1 is supplied to the clock input terminals CKA, and the clock signal CK2 is supplied to the clock input terminals CKB. In the alternate j-numbered shift register stages SR that start from the second shift register stage SR3, the clock signal CK2 is supplied to the clock input terminals CKA, and the clock signal CK1 is supplied to the clock input terminals CKB. In this manner, the first and second stages are aligned alternately in the first shift register 51a.

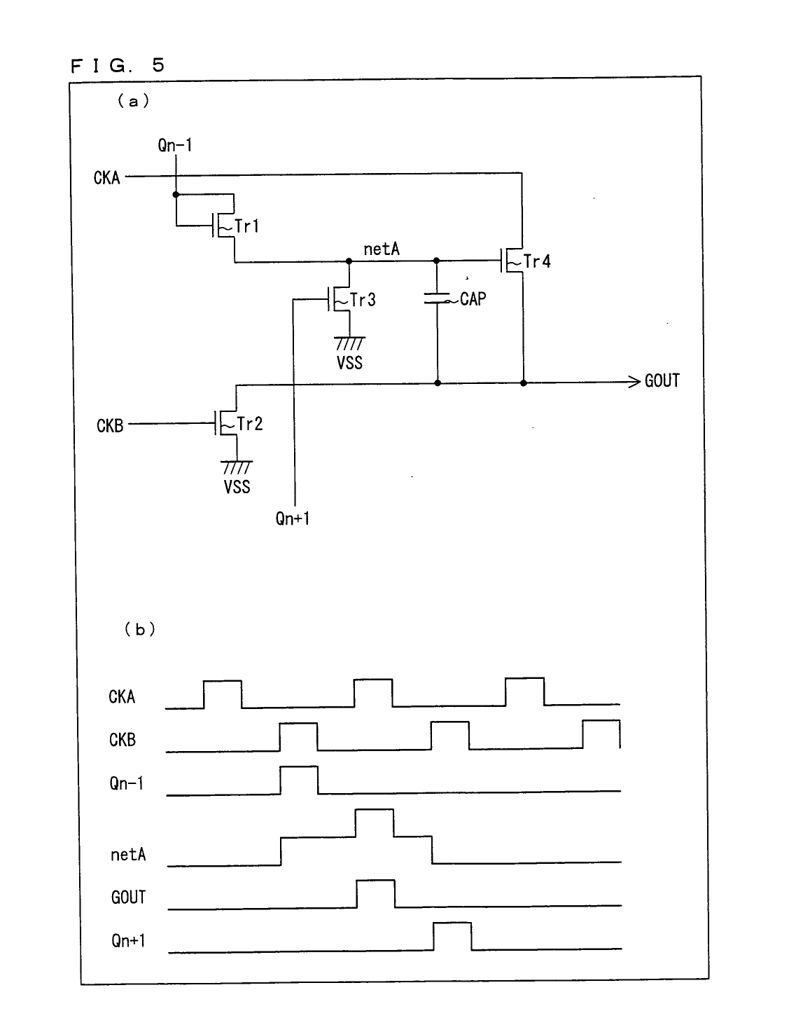

The clock signals CK1 and CK2 have waveforms as shown in (b) of FIG. 5 (see CKA and CKB for CK1 and CK2, respectively). The clock signals CK1 and CK2 are arranged so that their clock pulses do not overlap each other. In addition, timings for the clock signals CK1 and CK2 are such that the clock pulse of the clock signal CK1 appears after a one clock pulse delay subsequent to the clock pulse of the clock signal CK2, and the clock pulse of the clock signal CK2 appears after a one clock pulse delay subsequent to the clock pulse of the clock signal CK1.

The gate driver 5b includes a second shift register 51b having a plurality of cascaded shift register stages SR (SR2, SR4, SR6, . . . ) therein. Each of the shift register stages SR includes a set input terminal Qn−1, an output terminal GOUT, a reset input terminal Qn+1, clock input terminals CKA and CKB, and a Low power source input terminal VSS. From the control board 4 are supplied a clock signal CK3, a clock signal CK4, a gate start pulse GSP2, and the Low power source VSS.

In the second shift register 51b, an output from the output terminal GOUT of a k-numbered (k=1, 2, 3, . . . , i=2, 4, 6, . . . , k=i/2) shift register stage SRi is a gate output Gi to be outputted to an i-th gate bus line GLi.

To the set input terminal Qn−1 of a first shift register stage SR2 that lies at one of opposite ends in the scanning direction, the gate start pulse GSP2 is supplied. To the respective set input terminals Qn−1 of the k-numbered second and succeeding shift register stages SRi, gate outputs Gi−2 of preceding shift register stages SRi−2 are supplied. Further, to the respective reset input terminals Qn+1 thereof, gate outputs Gi+2 of subsequent shift register stages SRi+2 are supplied.

In the alternate k-numbered shift register stages SR that start from the first shift register stage SR2, the clock signal CK3 is supplied to the clock input terminals CKA, and the clock signal CK4 is supplied to the clock input terminals CKB. In the alternate k-numbered shift register stages SR that start from the second shift register stage SR4, the clock signal CK4 is supplied to the clock input terminals CKA, and the clock signal CK3 is supplied to the clock input terminals CKB. In this manner, the third and fourth stages are aligned alternately in the second shift register 51b.

The clock signals CK3 and CK4 have waveforms as shown in (b) of FIG. 5 (see CKA and CKB for CK3 and CK4, respectively). The clock signals CK3 and CK4 are arranged so that their clock pulses do not overlap each other. In addition, timings for the clock signals CK3 and CK4 are such that the clock pulse of the clock signal CK3 appears after a one clock pulse delay subsequent to the clock pulse of the clock signal CK4, and the clock pulse of the clock signal CK4 appears after a one clock pulse delay subsequent to the clock pulse of the clock signal CK3.

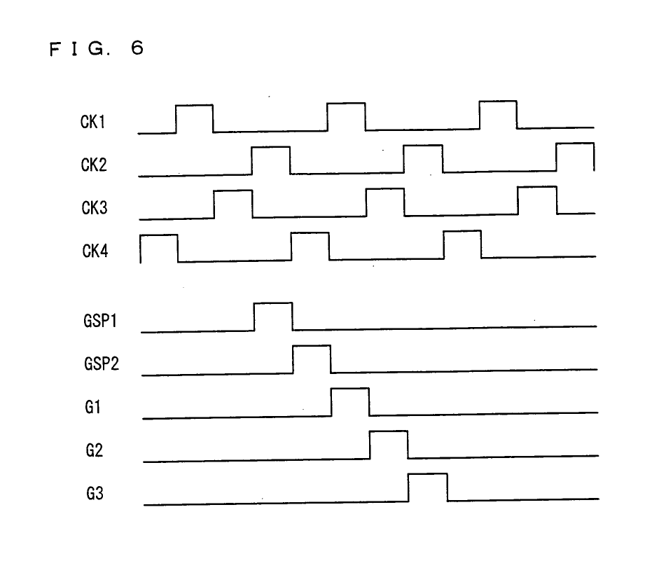

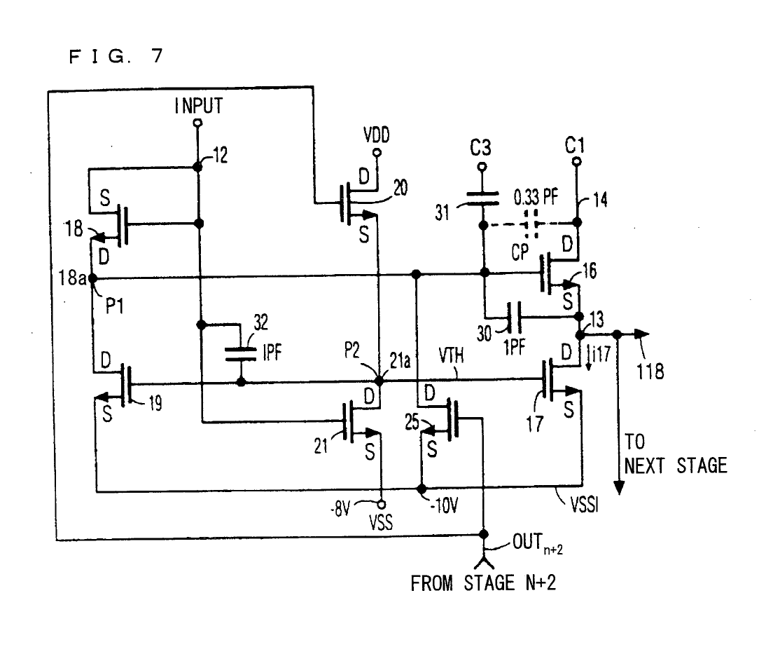

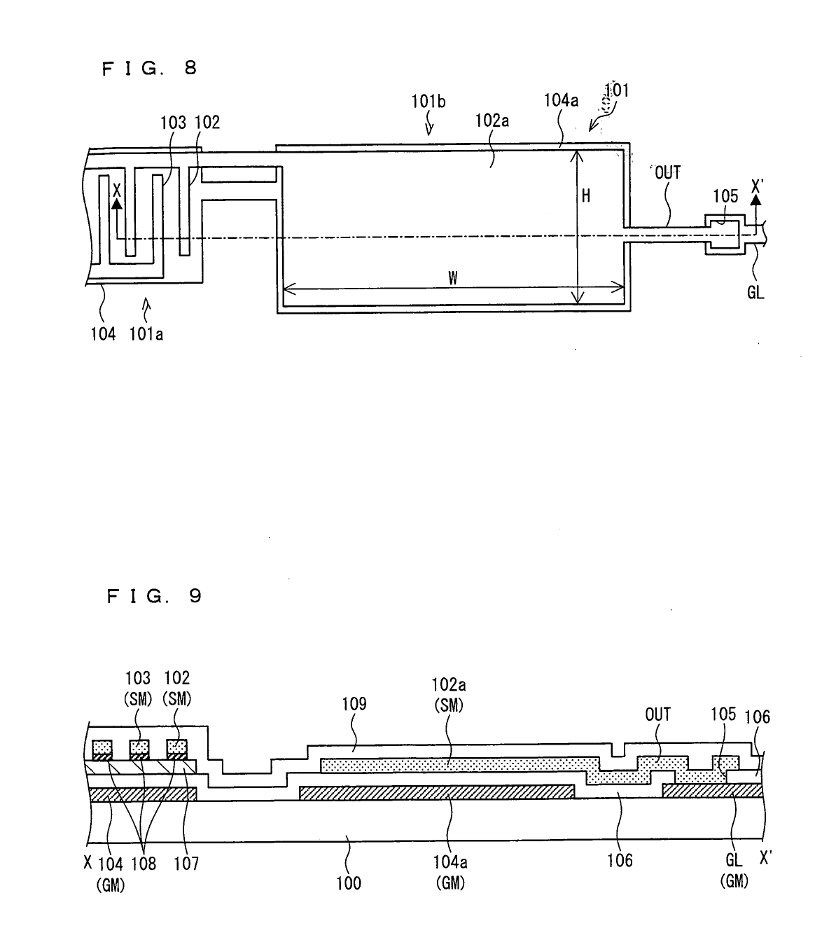

Further, as shown in FIG. 6, the clock signals CK1, CK2, CK3, and CK4 are out of sync with each other. Timings for the clock signals CK1, CK2, CK3, and CK4 are such that the clock pulse of the clock signal CK1 appears subsequently to the clock pulse of the clock signal CK4, the clock pulse of the clock signal CK3 appears subsequently to the clock pulse of the clock signal CK1, the clock pulse of the clock signal CK2 appears subsequently to the clock pulse of the clock signal CK3, and the clock pulse of the clock signal CK4 appears subsequently to the clock pulse of the clock signal CK2.

As shown in FIG. 6, the gate start pulses GSP1 and GSP2 are pulses such that the gate start pulse GSP1 precedes the gate start pulse GSP2 and the gate start pulses GSP1 and GSP2 are adjacent to each other. The pulse of the gate start pulse GSP1 is in synchronism with the clock pulse of the clock signal CK2, and the pulse of the gate start pulse GSP2 is in synchronism with the clock pulse of the clock signal CK4.

Next, the following will describe the configuration of the shift register stage SRi of the shift registers 51a and 51b with reference to (a) of FIG. 5.

The shift register stage SRi includes transistors Tr1, Tr2, Tr3, and Tr4. Particularly, the transistor Tr4 includes a bootstrap capacitor CAP. These transistors are all n-channel type TFTs.

As to the transistor Tr1, a gate and a drain are connected to a set input terminal Qn−1, and a source is connected to a gate of the transistor Tr4. As to the transistor Tr4, a drain is connected to a clock input terminal CKA, and a source is connected to an output terminal GOUT. That is, the transistor Tr4 serves as a transfer gate to perform passage and interruption of a clock signal to be supplied to the clock input terminal CKA. The capacitor CAP is provided between the gate and the source of the transistor Tr4. A node that is set to the same potential as the gate of the transistor Tr4 is referred to as a netA.

As to the transistor Tr2, a gate is connected to the clock input terminal CKB, a drain is connected to the output terminal GOUT, and a source is connected to the Low power source input terminal VSS. As to the transistor Tr3, a gate is connected to the reset input terminal Qn+1, a drain is connected to the node netA, and a source is connected to the Low power source input terminal VSS.

Next, with reference to (b) of FIG. 5, the following will describe the operations of the shift register stage SRi configured as shown in (a) of FIG. 5.

When a shift pulse is supplied to the set input terminal Qn−1, the transistor Tr1 is turned ON, which charges the capacitor CAP. For the shift register stages SR1 and SR2, the shift pulse corresponds to the gate start pulses GSP1 and GSP2, respectively. For the other shift register stages SRi, the shift pulse corresponds to gate outputs Gj−1 and Gk−1 from preceding shift register stages. Charging of the capacitor CAP increases a potential of the node netA and causes the transistor Tr4 to be turned ON. This causes the clock signal supplied through the clock input terminal CKA to appear in the source of the transistor Tr4. At the instant when the subsequent clock pulse is supplied to the clock input terminal CKA, the potential of the node netA rapidly increases due to the bootstrap effect of the capacitor CAP, and the incoming clock pulse is transferred to the output terminal GOUT of the shift register stage SRi and outputted from the output terminal GOUT as a gate pulse.

When the supply of the gate pulse to the set input terminal Qn−1 is completed, the transistor Tr4 is turned OFF. Then, in order to release charge retention caused by floating of the node netA and the output terminal GOUT of the shift register stage SRi, the transistor Tr3 is turned ON by a reset pulse supplied to the reset input terminal Qn+1. This causes the node netA and the output terminal GOUT to be set to a potential of the Low power source VSS.

Thereafter, until the shift pulse is supplied to the set input terminal Qn−1 again, the transistor Tr2 is periodically turned ON by the clock pulse supplied to the clock input terminal CKB. This refreshes the node netA and the output terminal GOUT of the shift register stage SRi with Low power source potential, i.e. sinks the gate bus line GLi voltage down.

In this manner, the gate pulses are sequentially outputted to the gate bus lines G1, G2, G3, and the like as shown in FIG. 6.

Next, the structures of elements applied to the transistor Tr4 in (a) of FIG. 5 will be described.

FIG. 1 shows a plan view of the structure of a TFT 61 applicable to the transistor Tr4 and provided on the display panel 2.

The TFT 61 includes a TFT body section 61a and a capacitor 61b. The capacitor 61b is a capacitor capable of serving as a bootstrap capacitor and applicable to the capacitor CAP.

The TFT body section 61a has a comb-shaped source electrode 62 and a comb-shaped drain electrode 63 disposed above a gate electrode 64 in a thickness direction and opposed to each other in a panel plane in such a manner that the source electrode 62 and drain electrode 63 are engaged with each other, which secures a large channel width. However, this is merely one arrangement example. The source electrode 62, the drain electrode 63, and the gate electrode 64 may be disposed at any positions with any shapes.

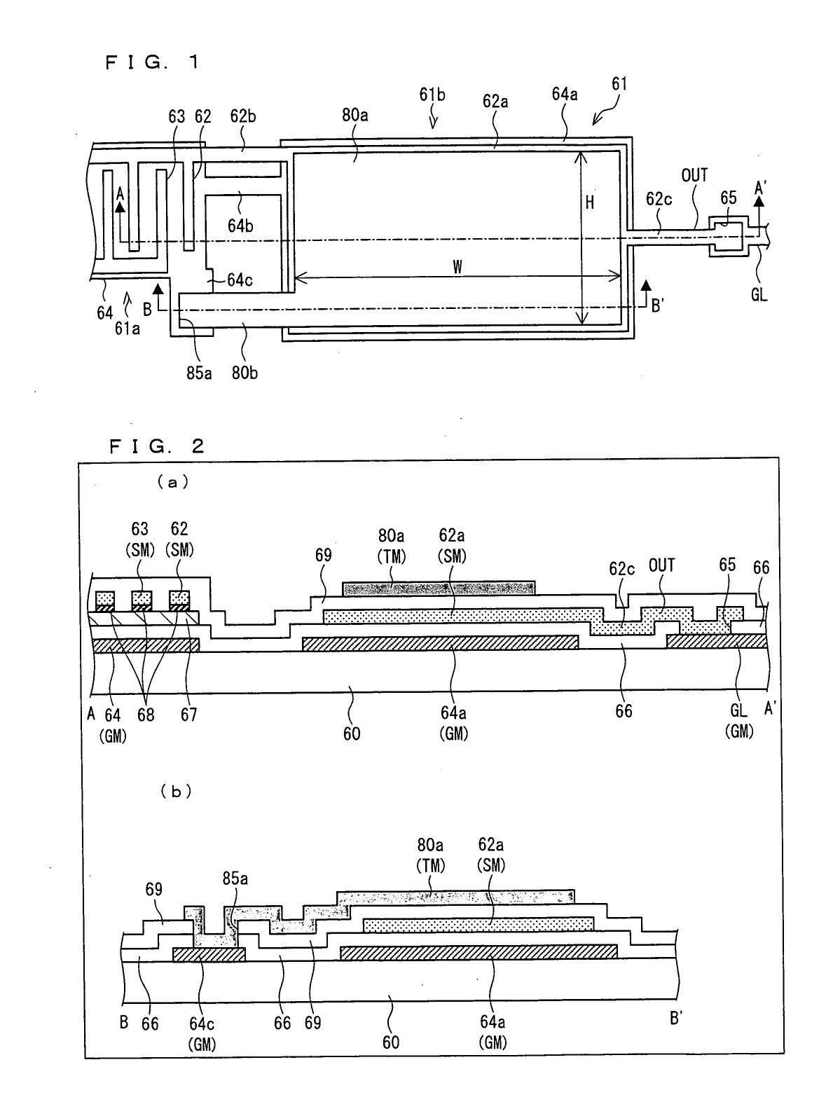

The capacitor 61b is formed so as to have a region where a first capacitor electrode 62a and a second capacitor electrode 64a are arranged to be stacked in the thickness direction and mutually opposed across a gate dielectric layer (first dielectric layer, see FIG. 2) 66 therebetween. The capacitor 61b is also formed so as to have a region where the first capacitor electrode 62a and a third capacitor electrode 80a are arranged to be stacked in the thickness direction and mutually opposed across a passivation layer (second dielectric layer, see FIG. 2) 69 therebetween, with a coupling between the first capacitor electrode 62a and the third capacitor electrode 80a and a coupling between the first capacitor electrode 62a and the second capacitor electrode 64a formed over mutually opposite faces of the first capacitor electrode 62a. The first capacitor electrode 62a is formed so as to be led out from the source electrode 62 of the TFT body section 61a through a lead-out line 62b in a planar direction. The second capacitor electrode 64a is formed so as to be led out from the gate electrode 64 of the TFT body section 61a through a lead-out line 64h in a planar direction. The third capacitor electrode 80a is formed from a transparent electrode (see FIG. 2) TM or a reflecting electrode. From the third capacitor electrode 80a, a lead-out line 80b is led out in a planar direction, and the lead-out line 80b is connected via a contact hole 85a to a lead-out line 64c that has been led out from the gate electrode 64 in a planar direction.

The first capacitor electrode 62a is connected to an output OUT of the shift register stage SR via a lead-out line 62c in a planar direction. The output OUT is connected via a contact hole 65 to the gate bus line GL which lies at a lower position in the thickness direction.

For example, the capacitor 61b in FIG. 1 has such a size that: one side H along a gate scanning direction is 50 μm, and the other side W orthogonal to the side H is 134 μm to 200 μm.

(a) of FIG. 2 shows a cross-sectional view taken along the line A-A′ in FIG. 1, and (b) of FIG. 2 shows a cross-sectional view taken along the line B-B′ in FIG. 1.

As shown in the cross-sectional view in (a) and (b) of FIG. 2, the arrangement in FIG. 1 is such that: a gate metal GM, the gate dielectric layer 66, an i layer 67 formed from Si, an n+ layer 68 formed from Si, a source metal SM, a passivation layer 69, and a transparent electrode TM or reflecting electrode are stacked on a glass substrate 60 in this order. The gate electrode 64, the second capacitor electrode 64a, and the gate bus line GL are all formed from the gate metal GM that has been formed in a concurrent manufacturing process. For example, the gate metal GM can be used in a single layer of Ta (or TaN), Ti (or TiN), Al (or an alloy whose major component is Al), Mo (or MoN), or Cr or used in a stack with any combinations of these metals. The source electrode 62, the drain electrode 63, the first capacitor electrode 62a, the lead-out line 62c, and the interconnection 62c are all formed from the source metal SM that has been formed in the concurrent manufacturing process. The source metal SM can be formed from the same material(s) as the material(s) for the gate metal GM. For example, the source metal SM can be used in a single layer of Ta (or TaN), Ti (or TiN), Al (or an alloy whose major component is Al), Mo (or MoN), or Cr or used in a stack with any combinations of these metals. Further, the third capacitor electrode 80a is formed from a transparent electrode TM or a reflecting electrode which is formed in a concurrent manufacturing process with the pixel electrode. For example, the transparent electrode TM can be formed from ITO (Indium Tin Oxide), IZO (Indium Zinc Oxide), or the like material. The reflecting electrode can be used in a single layer of Al or an alloy whose major component is Al, Mo, or Ag or used in a stack with any combinations of these metals.

As the gate dielectric layer 66, for example, SiN, SiO₂, or the like material can be used. As the passivation layer 69, for example, SiN, SiO₂, an organic resin film, or the like material can be used.

The i layer 67 is a layer that serves as a channel forming region in the TFT body section 61a. The n+ layer 68 is provided as a source/drain contact layer between the i layer 67 and the source electrode 62 and between the i layer 67 and the drain electrode 63.

Besides, in FIG. 1, the lead-out line 64b is formed from the gate metal GM, and the lead-out line 62b is formed from the source metal SM.

Further, the capacitor 61b is arranged such that capacitance formed between the first capacitor electrode 62a and the second capacitor electrode 64a is connected in parallel to capacitance formed between the first capacitor electrode 62a and the third capacitor electrode 80a. Therefore, under the conditions where the gate dielectric layer 66 is equal in thickness to the passivation layer 69, a footprint of the capacitor 61b on the panel, which area is determined by H×W as described above, can be reduced to about one half, as compared with the conventional arrangement without parallel connection. Further, under the conditions where a layer thickness of the passivation layer 69 is one half of that of the gate dielectric layer 66, a footprint of the capacitor 61b can be reduced to about one third, as compared to the conventional arrangement without parallel connection. This makes it possible to reduce a width of a picture frame region of the display device by 200 μm to 256 μm, as compared with the conventional arrangement. That is, it is possible to reduce the picture frame size. This, in turn, eliminates the need for increase of a footprint of the capacitor element of the TFT 61 on the panel.

The present embodiment has been described above. In the above example, the transparent electrode TM or the reflecting electrode is located across the source metal SM more above than the gate metal GM, when viewed in the thickness direction. However, this is not the only possibility. The locations of the gate metal GM and the transparent electrode TM or the reflecting electrode may be reversed as long as the source metal SM is provided between the gate metal GM and the transparent electrode TM or the reflecting electrode.

Further, gate drivers can be provided so as to adjoin to opposite sides of the display region 2a or to adjoin to one of the opposite sides of the display region 2a. Thus, the gate driver(s) may be positioned at a desired place(s).

Still further, the TFT may be used at any spot in a display device, or may be used at a place other than the display device.

Yet further, the present invention can be applied to any other display devices such as an electroluminescent display device, without limitation to a liquid crystal display device.

The present invention is not limited to the aforementioned embodiments and is susceptible of various changes within the scope of the accompanying claims. Also, an embodiment obtained by suitable combinations of technical means disclosed in the different embodiments are also included within the technical scope of the present invention.

### INDUSTRIAL APPLICABILITY

The present invention can be suitably used for a display device including a TFT.

1. A TFT comprising:
a capacitor formed: so as to have a region where a first capacitor electrode connected to a source electrode and a second capacitor electrode connected to a gate electrode are arranged to be stacked in a thickness direction and mutually opposed across a first dielectric layer therebetween; and so as to have a region where the first capacitor electrode and a third capacitor electrode connected to the gate electrode are arranged to be stacked in the thickness direction and mutually opposed across a second dielectric layer therebetween with a coupling between the first capacitor electrode and the third capacitor electrode and a coupling between the first capacitor electrode and the second capacitor electrode formed over mutually opposite faces of the first capacitor electrode.

2. The TFT according to claim 1, wherein
the first capacitor electrode is formed from source metal,
the second capacitor electrode is formed from gate metal, and
the third capacitor electrode is formed from a transparent electrode or a reflecting electrode.

3. The TFT according to claim 1, wherein
the first dielectric layer is a gate dielectric layer, and
the second dielectric layer is a passivation layer.

4. The TFT according to claim 1, wherein
the third capacitor electrode is connected to the gate electrode, through contact with the gate electrode via a contact hole which is formed in a stack of the first and second dielectric layers.

5. The TFT according to claim 1, wherein
the TFT is manufactured with use of amorphous silicon.

6. The TFT according to claim 1, wherein
the TFT is manufactured with use of microcrystalline silicon.

7. A shift register including a plurality of stages composed of transistors, wherein
at least one of the transistors is a TFT according to claim 1.

8. A scanning signal line drive circuit including a shift register according to claim 7, wherein
the shift register is used to generate a scan signal for a display device.

9. The scan signal line driving circuit according to claim 8, wherein
the TFT is an output transistor that outputs the scan signal.

10. The scan signal line driving circuit according to claim 9, wherein
from the first capacitor electrode, a lead-out line connected via a contact hole to a scan signal line is led out.

11. A display device, comprising a scan signal line driving circuit according to claim 8.

12. The display device according to claim 11, wherein
the scan signal line driving circuit is formed on a display panel so as to be monolithically integrated with a display region.

13. A display device, comprising a display panel in which a TFT according to claim 1.
